(19) United States
(12) Patent Application Publication
(10) Pub. No.: US 2012/0292756 A1
(43) Pub. Date: Nov. 22, 2012

(54) SEMICONDUCTOR DEVICE WITH HEAT SPREADER

(75) Inventor: Weidong HUANG, Tianjin (CN)

(73) Assignee: FREESCALE SEMICONDUCTOR, INC, Austin, TX (US)

(21) Appl. No.: 13/461,799

(22) Filed: May 2, 2012

(30) Foreign Application Priority Data
May 17, 2011 (CN) 201110127297.4

(51) Int. Cl. H01L 23/498; H01L 21/56

(52) U.S. Cl. 257/680; 438/122; 257/E23.069; 257/E21.502

(57) ABSTRACT

A semiconductor device has a semiconductor die attached to a second side of a heat spreader plate. The second side of the heat spreader plate is attached to a first side of a substrate with thermal balls. The substrate includes a window within which the semiconductor die is arranged and there is a gap between an edge of the die and an edge of the window. The die is electrically connected to a second side of the substrate such as with wires. The die, electrical connections to the substrate, and thermal balls are then encapsulated with a mold compound. Connection bumps may be attached to the second side of the substrate for device I/Os. Heat generated by the die during operation dissipates along the thermal path from the backside of the semiconductor die through the heat spreader plate.

### BACKGROUND OF THE INVENTION

The present invention relates generally to a semiconductor device having a thermal path for conducting heat away from the semiconductor die, and more particularly to a semiconductor device such as a ball grid array (BGA) semiconductor package with enhanced thermal dissipation capability.

Semiconductor integrated circuits and devices are frequently packaged in different chip carrier configurations such as a ball grid array (BGA) type package. Such packages protect the delicate and fragile semiconductor die and electrical connections to and from the die. The semiconductor packages are reliable and are produced in high volumes. There is a demand for semiconductor packages in practical applications in a number of industries ranging from computing and hand-held electronic devices to automotive and industrial environments.

A BGA package comprises a semiconductor die mounted on the top side of a multi-layer substrate (e.g., a printed circuit board (PCB)) where the bottom or under side of the PCB has an array of solder balls arranged to contact a surface such as another PCB to interconnect with external circuitry. The industry continuously demands semiconductor packages with higher performance integrated circuits and devices with smaller footprints and thicknesses. As the power and speed requirements increase and die size decreases, the amount of heat generated by the integrated circuits and devices increases. If the generated heat is not effectively dissipated, the performance of the device may be hampered and could lead to a malfunction.

Thus, there is a need to address or at least alleviate the above problems by enhancing thermal dissipation capability of semiconductor packages such as BGA semiconductor packages.

### BRIEF DESCRIPTION OF THE DRAWINGS

The accompanying drawings incorporated herein and forming a part of the specification illustrate several aspects of the present invention and, together with the description, serve to explain the principles of the invention. While the invention will be described in connection with certain embodiments, there is no intent to limit the invention to those embodiments described. On the contrary, the intent is to cover all alternatives, modifications and equivalents as included within the scope of the invention as defined by the appended claims. In the drawings:

FIG. 1 is a top plan view of a substrate for a semiconductor device in accordance with an embodiment of the invention;

FIG. 2 is a cross-sectional view of the substrate shown in FIG. 1 taken along line 1-1 in accordance with an embodiment of the invention;

FIGS. 3-8 are cross-sectional views illustrating different assembly steps of a ball grid array (BGA) semiconductor device in accordance with an embodiment of the invention;

FIG. 9 is a 180° rotated view of the cross-sectional view of the BGA semiconductor device shown in FIG. 8 in accordance with an embodiment of the invention;

FIG. 10 is a cross-sectional view of a BGA semiconductor device including a heat spreader plate with an exposed in accordance with an embodiment of the invention;

FIG. 11 is a top plan view of a substrate with a thermal ball arrangement in accordance with an embodiment of the invention;

FIG. 12 is a bottom plan view of a substrate with a solder ball arrangement in accordance with an embodiment of the invention; and

FIG. 13 is a flow chart of a method of assembling a BGA device in accordance with an embodiment of the invention.

### DETAILED DESCRIPTION OF THE INVENTION

An aspect of the invention is a semiconductor device with a thermal path comprising a substrate with a first side and a second side; a heat spreader plate having a first surface and a second surface; a first plurality of conductive bumps arranged to thermally connect the first side of the substrate and the second surface of the heat spreader plate; a chip or semiconductor die having a top side and a bottom side, the chip arranged to thermally connect the bottom side of the chip with the second surface of the heat spreader plate, and to electrically connect the top side of the chip with the second side of the substrate; and a molding compound encapsulating the chip and the first plurality of conductive bumps.

An embodiment of the invention further comprises a second plurality of conductive bumps arranged on the second side of the substrate forming the inputs and outputs of the semiconductor device. The substrate may have a window. The window may have an edge side and the chip has an edge side, and the chip is located within the window and there is a gap between the edge side of the window and the edge side of the chip. The molding compound encapsulates the first surface of the heat spreader plate. The first surface of the heat spreader plate may be exposed. The first plurality of bumps may be smaller than, larger than, or the same size as the second plurality of bumps. The first plurality of bumps comprises thermal balls.

An aspect of the invention is a method of assembling a semiconductor device with a thermal path comprising attaching a first plurality of conductive bumps to thermally connect a first side of a substrate to a second surface of a heat spreader plate; arranging a chip or semiconductor die to thermally connect a back side of the chip with a second surface of the heat spreader plate, and to electrically connect a top side of the chip with a second side of the substrate; and encapsulating the chip and the first plurality of conductive bumps with a molding compound.

An embodiment of the invention further comprises attaching a second plurality of conductive bumps on the second side of the substrate to form inputs and outputs of the semiconductor device. The substrate may be arranged with a window, where the window has an edge side and the chip has an edge side, and the chip is arranged within the window and there is a gap between the edge side of the window and the edge side of the chip. The encapsulating may further comprise encapsulating the first surface of the heat spreader plate. The encapsulating may extend to the first surface of the heat spreader plate and the first surface of the heat spreader plate may remain exposed.

A semiconductor device and a method for assembling a semiconductor device with a heat dissipating area with a thermal path to transfer and dissipate heat from the back side of a semiconductor die of the semiconductor device is disclosed. The thermal path of the heat dissipating area of the semiconductor device comprises a heat spreader plate having a first side bonded to the back side of the semiconductor die, and a plate fixed to the first side of the heat spreader plate with an array of thermal balls, bumps, or the like. Heat generated by the semiconductor die during operation dissipates along the thermal path from the back side of the semiconductor die through the heat spreader plate, which enhances the thermal dissipation capability of the semiconductor package.

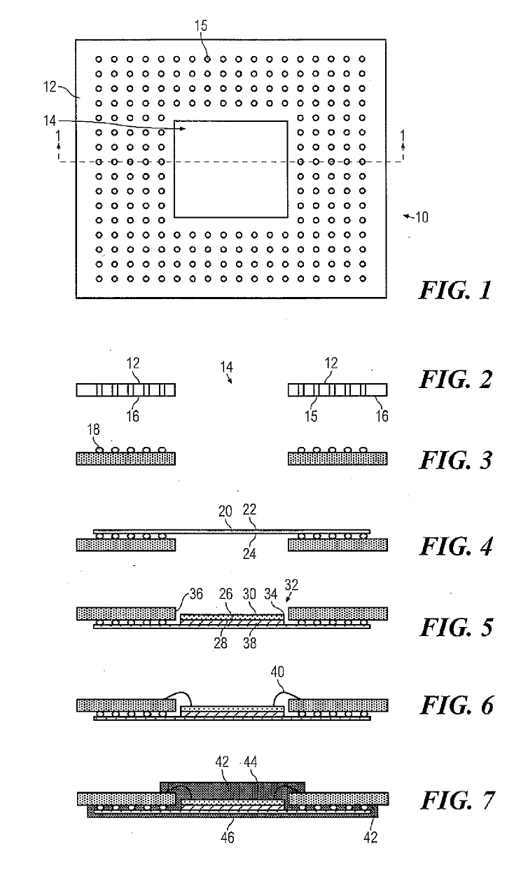

Referring now to FIG. 1, a top plan view of a substrate 10 is shown for a semiconductor device in accordance with an embodiment of the invention. The substrate 10 has a first side or surface 12, a window 14, and electrical vias 15 that form passages through the first side 12 to a bottom side or surface to provide electrical pathways for the electrical interconnection of components and devices of the semiconductor device. FIG. 2 is a cross-sectional view of the substrate 10 taken along dashed line 1-1 of FIG. 1. FIG. 2 shows the second side or surface 16 of the substrate 10. For illustrative purposes, in an embodiment, the substrate 10 has a thickness in the range of approximately 0.2 mm to 1 mm, and a generally rectangular or square configuration having a side length in the range of approximately 15 mm to 50 mm. The window 14 also is rectangular or square having a side length in the range of approximately 6 mm to 20 mm. It will be appreciated that the actual dimensions of the plate 10 and the window 14 may take different configurations and forms. The dimensions provided here are just examples provided for illustrative purposes. The substrate 10 may be a multi-layer printed circuit board (PCB) or lead frame fabricated of a material such as bismaleimide triazine (BT) epoxy/glass laminate with rolled copper traces on each side or the like. The window 14 and vias 15 are bored, drilled or the like in the substrate 10. The substrate 10 may have a dry or wet film solder mask to ensure that all of the vias 15 are completely tented.

As shown in FIG. 3, a first set or plurality of thermal balls 18 or bumps are attached or gang dipped to solder pads (not shown) on the first side 12 of the substrate 10. The pattern of the thermal solder pads and thermal balls 18 may form a ball grid array of any number of patterns. For illustrative purposes, in an embodiment, the size or diameter of the first set of thermal balls 18 is in the range of approximately 0.1 mm to 0.5 mm, having a pitch of approximately 1 mm, and the thermal balls 18 may have a uniform size, dimension and material. It will be appreciated that the actual dimensions, materials and pitch of the thermal balls 18 may take different configurations and forms, for example different thermal balls in an array on a substrate may have different materials. The dimensions and materials provided here are just examples provided for illustrative purposes.

The material of the thermal balls 18 is a thermally conductive material. Examples of the thermally conductive material are metals, alloys and the like, such as lead-tin (PbSn) alloy, tin-silver-copper (SnAgCu) alloy, straight eutectic (63% Sn/37% Pb) solder balls with a melting temperature of 183° C., near eutectic (62% Sn/36% Pb/2% Ag) solder balls, or the like. The thermal balls 18 are formed by conventional solder ball machinery.

FIG. 4 shows a heat spreader plate 20 having a first side 22 and a second side 24 arranged on the thermal balls 18 such that the second side 24 of the heat spreader plate 20 contacts the thermal balls 18. The second side 24 of the heat spreader plate also has a reciprocal solder pad arrangement (not shown) to match the thermal ball array on the first side 12 of the substrate 10. A reflow operation may be performed on the plate 10, thermal balls 18, and heat spreader plate 20 assembly.

The heat dissipating area of the semiconductor device comprises the heat spreader plate 20. The heat spreader plate 20 is made of a material having a good heat transfer rate such as copper, copper alloy, or the like. For example, the core material of the heat spreader plate 20 in an embodiment is copper (Cu) with plated aluminium (Al) and an oxygenation layer. The thickness of the heat spreader plate 20 may be approximately 0.3 mm to 0.5 mm. The actual dimensions of the heat spreader plate 20 depend on specific requirements and specifications suitable for any particular application.

FIG. 5 shows the assembly of FIG. 4 rotated 180°. In FIG. 5, a semiconductor die or chip 26 including integrated circuits and/or devices is placed on the second side 24 of the heat spreader plate 20 through the window 14 of the substrate 10. The chip 26 has a bottom surface or back side 28 and a top side or active surface 30. The window 14 is sized such that the chip 26 fits within the window 14 but side edges of the chip 26 do not contact side edges of the window 14. That is, the area dimensions of the chip 26 are less than the area dimensions of the window 14 such that there is a gap or space 32 between the side edges 34 of the chip 26 and the side edges 36 of the substrate 10. The chip 26 may have a thickness of approximately 0.1 μm to 0.5 μm and side length and width dimensions of approximately 5 mm to 15 mm. The back side 28 of the chip 26 is bonded to the second side 24 of the heat spreader plate 20 with die attach adhesive 38 with a thermal conductive resin such as epoxy containing silver, thermal enhanced epoxy die attach adhesive, and the like. In one embodiment, the thickness of the die attach adhesive 38 is approximately 40 μm.

FIG. 6 shows the top side or active surface 30 of the chip 26 electrically connected to the second side 16 of the substrate 10 with wires 40. The material of the wires 40 may be gold (Au), copper (Cu), and the like. The wires 40 are bonded from the top side 30 of the chip 26 to wire bond pads (not shown) on the second side 16 of the substrate 10 using a conventional wire bonding process and commercially available wire bonding equipment. Traces (not shown) in or on the substrate 10 from the wire bond pads interconnect the vias 15 in the substrate 10 to the second side 16 of the substrate for electrical interconnection with a set of solder pads (not shown) on the second side 16 of the substrate 10. The wires 40 electrically connect the bonding pads on the active surface 30 of the chip 26 to the bond pads on the second side 16 of the substrate 10. The bond pads on the second side 16 of the substrate 10 sometimes are referred to as “fingers”, which are the ends of the electrical conductive traces that may spread into various layers in the substrate 10 by way of the vias 15.

FIG. 7 shows a mold material 42, which may comprise an encapsulant overmold material, liquid mold material, glob-top mold material or the like, covering the chip 26, wires 40, and the first set of thermal balls 18. The mold material 24 may also cover the first side 22 of the heat spreader plate 20. The mold material 42 may be applied by a transfer molding process or the like to completely encapsulate and protect the fragile components of the semiconductor device such as the chip 26, wires 40, substrate wire bond pads, etc. The mold material 42 forms a protective cover with a first side or surface 44 and a second side or surface 46 that protects the semiconductor device components from external and ambient conditions such as moisture, strain, shock, vibration, dust, and the like. The mold material 42 may be an epoxy resin, or the like, and is chosen to meet the specific requirements of a particular application. Generally, the physical properties required for mold materials include spiral flow, gel time, viscosity, filler content, and the like. The thermal properties include glass transition temperature, coefficient of thermal expansion, thermal conductivity, and the like. All of the above mentioned properties and materials impact the molding process characterization and package reliability. However, such molding processes are well known in the art so a detailed description thereof is not required for a complete understanding of the present invention.

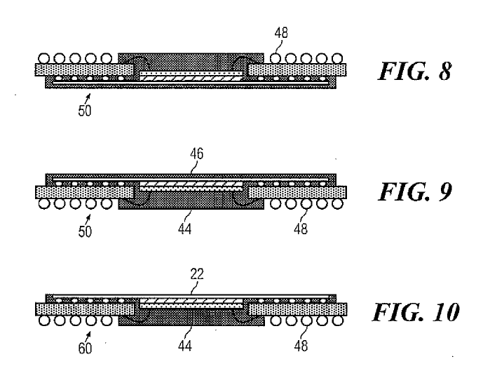

FIG. 8 shows a second set or plurality of conductive bumps 48, such as solder balls that are used to form a semiconductor device 50. The second set of conductive bumps 48 is attached or gang dipped to ball attach or solder pads (not shown) on the second side 16 of the substrate 10. The electrical traces end at the ball attach pads to which the conductive bumps 48 are bonded. The conductive bumps 48 may be arranged in a pattern to form a ball grid array of any number of patterns. For illustrative purposes, in an embodiment, the size of the second set of conductive bumps 48 is in the range of approximately 0.3 mm to 0.8 mm, and having a pitch of approximately 1 mm to 1.5 mm. It will be appreciated that the actual dimensions and pitch of the conductive bumps 48 may take different configurations and forms. The dimensions provided here are just examples provided for illustrative purposes.

As previously discussed, the material of the conductive bumps 48 may be the same or different material as the first set of thermal balls 18, and may be straight eutectic (63% Sn/37% Pb) solder balls with a melting temperature of 183° C., near eutectic (62% Sn/36% Pb/2% Ag) solder balls, or the like. The conductive bumps 48 are reflowed on the second side 16 of the substrate 10 onto solder pads (not shown) using conventional reflow processes such as for example forced convection reflow oven and a surface mount assembly with a maximum temperature such as 230°. The semiconductor device 50 can be attached to another surface such as a PCB to interconnect with external circuitry (not shown).

In this embodiment the semiconductor device 50 is a BGA type package that is known as a plastic BGA (PBGA). It will be appreciated that the configuration of the dissipating area of the semiconductor device 50 of this embodiment with the array of thermal balls 18 between the second side 24 of the heat spreader plate 20 and the first side 12 of the substrate 10, where the chip 26 is attached to the second side 24 of the heat spreader plate 20, may be applied to other semiconductor package types including for example flip chip packages, chip scale packages (CSP) such as for example redistribution chip package, and the like.

FIG. 9 is a 180° rotated view of the cross-sectional view of the BGA semiconductor device 50 shown in FIG. 8 in accordance with an embodiment of the invention. The mold material 42 in this embodiment encapsulates the heat spreader plate 20. FIG. 10 is a cross-sectional view of another embodiment of a BGA semiconductor device 60 in which the first side 22 of the heat spreader plate 20 is exposed to the external ambient environment such as air.

FIGS. 9 and 10 show BGA semiconductor device package configurations with heat dissipation area in accordance with embodiments of the invention in which the chip 26 is arranged face down and the bottom surface of the chip 26 is bonded to the heat spreader plate 20. The heat spreader plate 20 also is connected to the substrate 10 by the thermal balls 18, where the thermal balls 18 are introduced into the package as an enhanced thermal path to transfer heat from the back side 28 of the chip 26 to the heat spreader plate 20. With this dissipation area configuration, it has been shown in thermal simulation evaluations that the BGA device 50 shown in FIG. 9 exhibits a 150%-200% increased thermal performance over a conventional PBGA package.

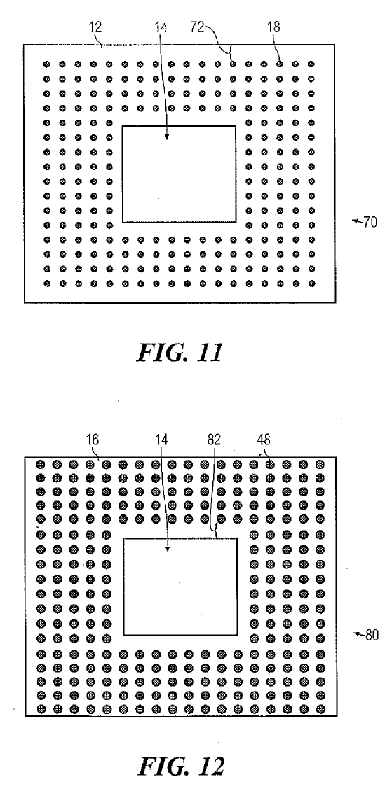

FIGS. 11 and 12 show thermal ball and solder ball arrangements or patterns, respectively, on the substrate 10. More specifically, FIG. 11 is a top plan view of a substrate with a thermal ball arrangement 70 in accordance with an embodiment of the invention. The thermal ball arrangement 70 shows the plurality of thermal balls 18 arranged on the first or top surface 12 of the substrate 10 around the substrate window 14. The thermal balls 18 in this arrangement are arranged within an area on the substrate 10, and not within an outer edge area or space 72 shown within the area bound by the perimeter of the substrate 10. No thermal balls are in the space 72 on the substrate surface 12 in order to allow for other processing steps of the semiconductor device such as the application of mold for the creation of the protective mold material 42 of the semiconductor device.

FIG. 12 is a bottom plan view of a substrate 10 with a conductive bump or solder ball arrangement 80 in accordance with an embodiment of the invention. The solder ball arrangement 80 shows the plurality of conductive bumps 48 arranged on the second or bottom surface 16 of the substrate 10 around the substrate window 14. The substrate 10 includes a clear area 82 proximate the window 14 in which no conductive bumps 48 are located in order to allow for other assembly steps such as the application of the mold forms for the creation of the protective mold material 42 of the semiconductor device.

Although the thermal balls 18 of FIG. 11 are shown smaller than the conductive bumps 48 of FIG. 12, the thermal balls 18 and conductive bumps 48 may be any size. The thermal balls 18 may be the same size, smaller, or larger than the conductive bumps 48. The size of the thermal balls 18 and the conductive bumps 48 selected is a design choice and may depend on the specific requirements for any particular application.

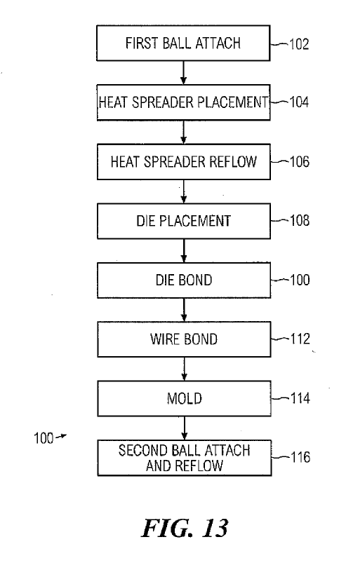

FIG. 13 is a flow chart of a method 100 of assembling a BGA semiconductor device in accordance with an embodiment of the invention. The method 100 follows the assembly steps illustrated with FIGS. 1-8. A first ball attach 102 is performed to attach the thermal bumps 18 to the first side 12 of the substrate 10. The heat spreader plate 20 is mounted or placed 104 into position, followed by reflow 106 to thermally attach the heat spreader plate 20 to the thermal balls 18 or thermal ball grid array to the substrate 10. The semiconductor die or chip 26 is placed 108 and bonded 110 to the heat spreader plate 20 with thermal conductive epoxy or resin. The chip 26 is electrically connected such as with a wire bonding process 112 to the substrate 10. The overmold or encapsulant material 42 is molded 114 over the components of the semiconductor device including the chip 26, wires 40, wire bond pads, the thermal ball grid array, and the like. A second ball attach 116 and reflow are performed to attach the conductive bumps 48 to the second side 16 of the substrate 10.

It will be appreciated that the above process was described with respect to a single semiconductor package for ease of description and illustration. Several semiconductor packages may be processed at the same time on a single substrate. The final step in the semiconductor device assembly then is singulation to separate individual semiconductor devices out of the larger substrate or panel.

Embodiments of the invention have been described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by the applicable law. Moreover, any combination of the above-described elements in all possible variations thereof is encompassed by the invention unless otherwise indicated herein or otherwise clearly contradicted by context.

1. A semiconductor device with a thermal path, comprising:
a substrate with a first side and a second side;
a heat spreader plate having a first surface and a second surface;
a first plurality of conductive bumps that thermally connect the first side of the substrate and the second surface of the heat spreader plate;
a chip having an top, active surface and an opposing bottom surface, wherein the bottom surface of the chip is attached to the second surface of the heat spreader plate, and wherein the top, active surface of the chip is electrically connected to the second side of the substrate; and
a molding compound encapsulating the chip, the first plurality of conductive bumps, and the electrical connections between the active surface of the chip and the second side of the substrate, wherein heat generated by the chip dissipates from the bottom surface of the chip to the second surface of the heat spreader plate and then to the first surface of the heat spreader plate.

2. The semiconductor device of claim 1, further comprising a second plurality of conductive bumps arranged on the second side of the substrate that form inputs and outputs of the semiconductor device.

3. The semiconductor device of claim 2, wherein the first plurality of bumps are smaller than the second plurality of bumps.

4. The semiconductor device of claim 2, wherein the first plurality of bumps are larger than the second plurality of bumps.

5. The semiconductor device of claim 2, wherein the first plurality of bumps are the same size as the second plurality of bumps.

6. The semiconductor device of claim 1, wherein the substrate has a window.

7. The semiconductor device of claim 6, wherein the window has an edge side and the chip has an edge side, and chip is arranged within the window such that there is a gap between the edge side of the window and the edge side of the chip.

8. The semiconductor device of claim 6, wherein the window is located centrally in the substrate.

9. The semiconductor device of claim 1, wherein the molding compound covers the first surface of the heat spreader plate.

10. The semiconductor device of claim 1, wherein the first surface of the heat spreader plate is exposed.

11. The semiconductor device of claim 1, wherein the first plurality of bumps are thermal balls.

12. A method of assembling a semiconductor device with a thermal path, comprising:
attaching a first plurality of conductive bumps to a first side of a substrate;
attaching a second surface of a heat spreader plate to the first side of the substrate by way of the conductive bumps;
attaching a back side of a chip to the second surface of the heat spreader plate, wherein the back side of the chip is thermally connected to the second surface of the heat spreader plate;
electrically connecting an active surface of the chip with a second side of the substrate; and
encapsulating the chip, the electrical connections and the first plurality of conductive bumps with a molding compound.

13. The method of claim 12, further comprising attaching a second plurality of conductive bumps on the second side of the substrate to form inputs and outputs of the semiconductor device.

14. The method of claim 13, wherein the first plurality of bumps are smaller than the second plurality of bumps.

15. The method of claim 13, wherein the first plurality of bumps are larger than the second plurality of bumps.

16. The method of claim 13, wherein the first plurality of bumps are the same size as the second plurality of bumps.

17. The method of claim 12, wherein the substrate has a window and the chip is arranged within the window, wherein there is a gap between a side edge of the window and a side edge of the chip.

18. The method of claim 12, wherein the encapsulating further comprises encapsulating the first surface of the heat spreader plate.

19. The method of claim 12, wherein the encapsulating extends to the first surface of the heat spreader plate and the first surface of the heat spreader plate remains exposed.

20. The method of claim 12, wherein the first plurality of bumps are thermal balls.
